(19) United States
(12) Patent Application Publication
(10) Pub. No.: US 2015/0280078 A1
(43) Pub. Date: Oct. 1, 2015

(54) WHITE FLIP CHIP LIGHT EMITTING DIODE (FC LED) AND FABRICATION METHOD

(71) Applicant: SemiLEDS Optoelectronics Co., Ltd., Chu-Nan (TW)

(72) Inventors: JUI-KANG YEN, Taipei City (TW); YUNG-WEI CHEN, Chu-Nan (TW); CHIH-HSUN CHEN, Chu-Nan (TW)

(73) Assignee: SemiLEDS Optoelectronics Co., Ltd., Chu-Nan (TW)

(21) Appl. No.: 14/230,040

(22) Filed: Mar. 31, 2014

(51) Int. Cl. H01L 33/50; H01L 33/06; H01L 33/60; H01L 33/00

(52) U.S. Cl. CPC H01L 33/50; H01L 33/005; H01L 33/06; H01L 33/60; H01L 2933/0041; H01L 2933/0058

(57) ABSTRACT

A white flip chip light emitting diode (FC LED) includes a flip chip (LED) die configured to emit electromagnetic radiation; reflective sidewalls on the (LED) die; and a wavelength conversion member having a uniform thickness and a surface area greater than or equal to a footprint of the flip chip (LED) die configured to change a wavelength of the electromagnetic radiation to produce white light. A method for fabricating the white flip chip light emitting diode (FC LED) includes the steps of: providing the flip chip (LED) die; forming reflective sidewalls on the flip chip (LED) die; and forming a wavelength conversion member on the flip chip (LED) die.

### FIELD

This disclosure relates to a white flip chip light emitting diode (FC LED) and to a method for fabricating the white (FC LED).

### BACKGROUND

Light emitting diodes (LED) have been developed that produce white light. In order to produce white light, a blue (LED) die can be used in combination with a wavelength conversion member, such as a phosphor layer formed on the surface of the die. The electromagnetic radiation emitted by the blue (LED) die excites the atoms of the wavelength conversion member, which converts some of the electromagnetic radiation in the blue wavelength spectral region to the yellow wavelength spectral region. The ratio of the blue to the yellow can be manipulated by the composition and geometry of the wavelength conversion member, such that the output appears to be white light.

In this type of white light emitting diode (LED), the characteristics of the white light are determined by the wavelength conversion properties of the wavelength conversion member. For example, the correlated color temperature (CCT) of the white light depends upon the spectral distributions of the electromagnetic radiation produced by the wavelength conversion member. Any variations in these spectral distributions can vary the correlated color temperature (CCT) producing an undesirable color balance. One factor that can affect the spectral distributions is the thickness of the wavelength conversion member.

One type of white light emitting diode, known as a flip chip light emitting diode (FC LED) includes an emitter side comprised of a sapphire substrate. The flip chip light emitting diode (FC LED) can also include a backside having an n-pad and a p-pad, which permits flip chip mounting to electrodes on a module substrate to form an (LED) system. A layer of solder can be used to bond the n-pad and the p-pad to the electrodes on the module substrate. During the packaging process, the solder layer can be deposited on the n-pad and the p-pad, and then reflowed during the module bonding process.

One problem that can occur in a flip chip light emitting diode (FC LED) is variations in the blue electromagnetic radiation emitted from the emitter side of the sapphire substrate. This problem is sometimes referred to as “blue leakage”. Blue leakage can occur because it is difficult to form the wavelength conversion member with a uniform thickness. Current dispensing and spray-coating techniques for forming the wavelength conversion member tend to produce a domed structure rather than a flat surface having a uniform thickness. In addition, electromagnetic radiation transmitted along the side walls of the sapphire substrate may not be directed through the wavelength conversion member causing the correlated color temperature (CCT) to vary.

The present disclosure is directed to a white flip chip light emitting diode (FC LED) having less blue leakage, improved color precision and uniformity, and a low profile. The present disclosure is also directed to a method for fabricating a white flip chip light emitting diode (FC LED) with decreased costs and reduced fabrication times, over prior art fabrication methods. However, the foregoing examples of the related art and limitations related therewith are intended to be illustrative and not exclusive. Other limitations of the related art will become apparent to those of skill in the art upon a reading of the specification and a study of the drawings. Similarly, the following embodiments and aspects thereof are described and illustrated in conjunction with a white flip chip light emitting diode (FC LED), which are meant to be exemplary and illustrative, not limiting in scope.

### SUMMARY

A white flip chip light emitting diode (FC LED) includes an emitter side configured to emit white light, and a backside having pads configured for bonding to electrodes on a module substrate. The white flip chip light emitting diode (FC LED) also includes a flip chip (LED) die comprising an epitaxial structure on a sapphire substrate configured to emit electromagnetic radiation; reflective sidewalls on the (LED) die; and a wavelength conversion member having a uniform thickness and an area equal to or greater than a footprint of the flip chip (LED) die configured to change a wavelength of the electromagnetic radiation to produce the white light. The white flip chip light emitting diode (FC LED) can also include a lens on the wavelength conversion member.

A method for fabricating a white flip chip light emitting diode (FC LED) includes the steps of: providing a flip chip light emitting diode (LED) die; forming reflective sidewalls on the (LED) die; and forming a wavelength conversion member on the (LED) die. The method can also include the steps of forming a lens on the wavelength conversion member; and flip chip mounting the (LED) die to electrodes on a module substrate to form a (LED) system.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1A is a schematic cross sectional view of a white flip chip light emitting diode (FC LED);

FIG. 1B is a schematic cross sectional view of an alternate embodiment white flip chip light emitting diode (FC LED) having a lens;

FIGS. 2A-2H are schematic cross sectional views illustrating steps in a method for fabricating the white flip chip light emitting diode (FC LED); and

FIG. 3 is a schematic side elevation view of the white flip chip light emitting diode (FC LED) flip chip mounted to a module substrate to form a (LED) system.

### DETAILED DESCRIPTION OF THE PREFERRED EMBODIMENTS

It is to be understood that when an element is stated as being “on” another element, it can be directly on the other element or intervening elements can also be present. However, the term “directly” means there are no intervening elements. In addition, although the terms “first”, “second” and “third” are used to describe various elements, these elements should not be limited by the term. Also, unless otherwise defined, all terms are intended to have the same meaning as commonly understood by one of ordinary skill in the art.

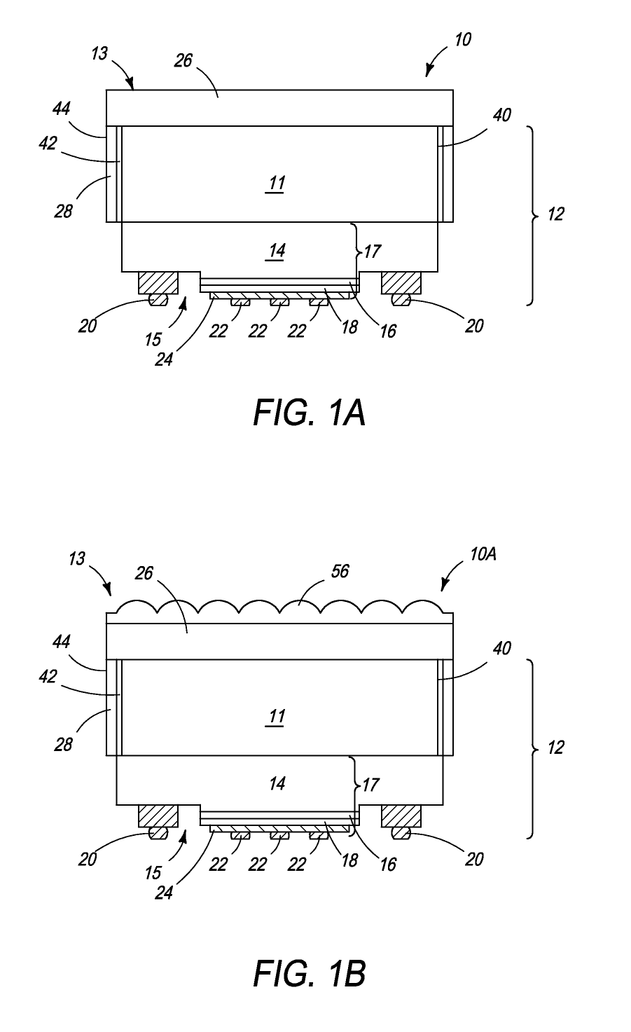

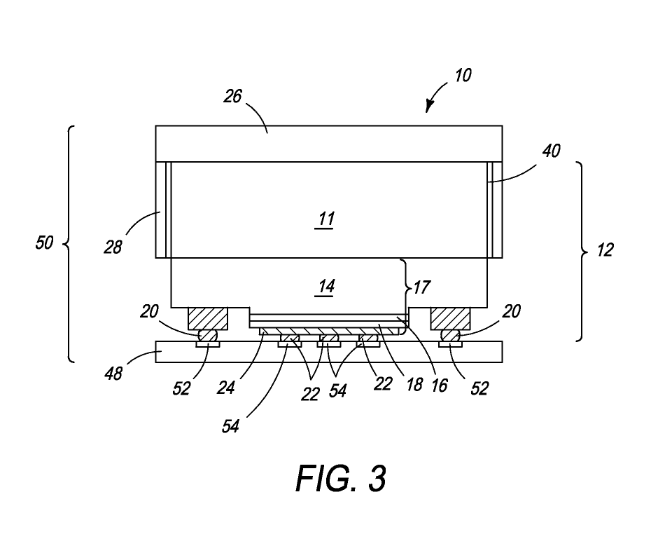

Referring to FIG. 1A, a white flip chip light emitting diode (FC LED) 10 is illustrated. The flip chip light emitting diode (FC LED) 10 includes an emitter side 13 configured to emit white light, and a backside 15 configured for flip chip mounting to a module substrate 48 (FIG. 3).

The white flip chip light emitting diode (FC LED) 10 also includes a flip chip (LED) die 12. The flip chip (LED) die 12 includes a sapphire substrate 11 proximate to the emitter side 13 having a planar surface 34, and an epitaxial structure 17 on the sapphire substrate 11. The epitaxial structure 17 includes an n-type confinement layer 14 on the sapphire substrate 11, a multiple quantum well (MQW) layer 16 in electrical contact with the n-type confinement layer 14 configured to emit electromagnetic radiation, and a p-type confinement layer 18 in electrical contact with the multiple quantum well (MQW) layer 16. By way of example, the sapphire substrate 11 can have a thickness of about 150 μm to 300 μm, and the epitaxial structure 17 can have a thickness of about 4 μm to 6 μm, such that the white flip chip light emitting diode (FC LED) 10 has a low profile.

The n-type confinement layer 14 preferably comprises n-GaN. Other suitable materials for the n-type confinement layer 14 include n-AlGaN, n-InGaN, n-AlInGaN, AlInN and n-AlN. The multiple quantum well (MQW) layer 16, which is also known as an active layer, can include one or more quantum wells comprising one or more layers of InGaN/GaN, AlGaInN, AlGaN, AlInN and AlN. The multiple quantum well (MQW) layer 16 can be configured to emit electromagnetic radiation from the visible spectral region (e.g., 400-770 nm), the violet-indigo spectral region (e.g., 400-450 nm), the blue spectral region (e.g., 450-490 nm), the green spectral region (e.g., 490-560 nm), the yellow spectral region (e.g., 560-590 nm), the orange spectral region (e.g., 590-635 nm) or the red spectral region (e.g., 635-700 nm). The p-type confinement layer 18 preferably comprises p-GaN. Other suitable materials for the p-type confinement layer 18 include p-AlGaN, p-InGaN, p-AlInGaN, p-AlInN and p-AlN.

As shown in FIG. 1A, the flip chip (LED) die 12 also includes a reflector layer 24 on the p-type confinement layer 18 comprising a highly reflective metal layer configured to reflect the electromagnetic radiation emitted by the multiple quantum well (MQW) layer 16 outward towards the emitter side 13. By way of example, the reflector layer 24 can comprise an Ag-based material having multiple layers, such as Ni/Ag/Ni/Au, Ag/Ni/Au, Ti/Ag/Ni/Au, Ag/Pt or Ag/Pd or Ag/Cr. The flip chip (LED) die 12 can also include additional electrically insulating layers as well as conductive layers, which for simplicity are not illustrated.

The flip chip (LED) die 12 also includes n-pads 20 and p-pads 22 on the backside 15 configured for bonding to electrodes 52, 54 on a module substrate 48 (FIG. 3) for flip chip mounting the white flip chip light emitting diode (FC LED) 10. In the illustrative embodiment, two n-pads 20 and three p-pads 22 are illustrated. However, it is to be understood that the flip chip (LED) die 12 can be provided with any number of n-pads 20 and p-pads 22. The n-pads 20 are in electrical contact with the n-type confinement layer 14. The p-pads 22 are formed on the reflector layer 24 in electrical contact with the p-type confinement layer 18. The n-pads 20 and the p-pads 22 can comprise a conductive material, such as a single layer of a metal, such as W, Ti, Mo, Al, Cu, Ni, Ag, Au or Co, a metal alloy such as Cu—Co or Cu—Mo, or a metal stack such as Ni/Cu or Ni/Cu—Mo.

The white flip chip light emitting diode (FC LED) 10 also includes a wavelength conversion member 26 on the planar surface 34 of the sapphire substrate 11 proximate to the emitter side 13 of the white flip chip light emitting diode (FC LED) 10. The wavelength conversion member 26 includes a material configured to convert at least some of the electromagnetic radiation emitted by the multiple quantum well (MQW) layer 16 into electromagnetic radiation having a different wavelength range. For example, the multiple quantum well (MQW) layer 16 can be configured to emit electromagnetic radiation in a blue spectral range, and the wavelength conversion member 26 can include a layer containing a phosphor compound for converting some of this radiation to a yellow spectral range to produce an electromagnetic radiation output for the white flip chip light emitting diode (FC LED) 10, which appears to be white light.

The wavelength conversion member 26 can comprise a transparent base material such as a polymer, a glass, or a ceramic containing a wavelength conversion compound, such as a phosphor compound. In addition, the wavelength conversion compound can be incorporated into the base material, using a mixing process to form a viscous mixture. Exemplary base materials for the wavelength conversion material include silicone, epoxy, spin on glass (SOG), SiO₂, and Al₂O₃ in liquid or viscous form, which can be mixed with the wavelength conversion compound in a specific ratio. Exemplary wavelength conversion compounds for the wavelength conversion material include YAG:Ce, TAG:Ce, alkaline earth silicon nitride doped with Eu, alkaline earth silicate doped with Eu, or calcium scandate doped with Ce.

The white flip chip light emitting diode (FC LED) 10 also includes reflective sidewalls 28 on the vertical sides 40 of the sapphire substrate 11. With the flip chip (LED) die 12 having a square or rectangular footprint, there are four reflective sidewalls oriented generally perpendicular to the planar surface 34 of the sapphire substrate 11. In the illustrative embodiment, the reflective sidewalls 28 are formed on the sides 40 of the sapphire substrate 11, but are not formed on the sides of the epitaxial structure 17. However, it is to be understood that in other embodiments the reflective sidewalls 28 can also be formed to completely or partially cover the sides of the epitaxial structure 17. The reflective sidewalls 28 prevent transmission of electromagnetic radiation from the quantum well (MQW) layer 16 through the vertical sides 40 of the sapphire substrate 11. The reflective sidewalls 28 can be formed of a highly reflective metal configured to reflect electromagnetic radiation, such as Ag, Al, Au, Cr, Pt, Pd or alloys of these metals. The reflective sidewalls 28 can also be formed as a stack of metals, as previously described for the reflector layer 24. In addition, the reflective sidewalls 28 include an isolation layer 42 on the vertical sides 40 of the sapphire substrate 11 configured to electrically insulate the reflective sidewalls 28 from the flip chip (LED) die 12. The reflective sidewalls 28 can also include a protective layer 44 on an outside surface thereof formed of a light transmissive material such as SiO₂.

The wavelength conversion member 26 has an area or footprint that is equal to or larger than the area or footprint of the flip chip (LED) die 12, which includes the sapphire substrate 11 with the reflective sidewalls 28 on the sides 40 thereof. With this area, all of the electromagnetic radiation transmitted through the sapphire substrate 11 must pass through the wavelength conversion member 26. In addition, the reflective sidewalls 28 prevent any electromagnetic radiation from passing through the vertical sides 40 of the sapphire substrate 11. Still further, the wavelength conversion member 26 has a uniform thickness across the entire footprint of the flip chip (LED) die 12. With these characteristics blue leakage is substantially eliminated, and improved color precision and uniformity are provided for producing white light. In addition, the white flip chip light emitting diode (FC LED) 10 has a low profile because the wavelength conversion member 26 can be thin and planar, rather than dome shaped as in the prior art. A thickness of the wavelength conversion member 26 can be selected as required with a range of from 50 μm to 300 μm being representative.

As shown in FIG. 1B, an alternate embodiment white flip chip light emitting diode (FC LED) 10A is identical to the white flip chip light emitting diode (FC LED) 10 shown in FIG. 1A, but also includes a lens 56 on the wavelength conversion member 26 configured to focus or collimate the white light. The lens 56 can comprise a transparent material having a desired thickness and shape. Suitable materials for the lens 56 include silicone, epoxy and glass.

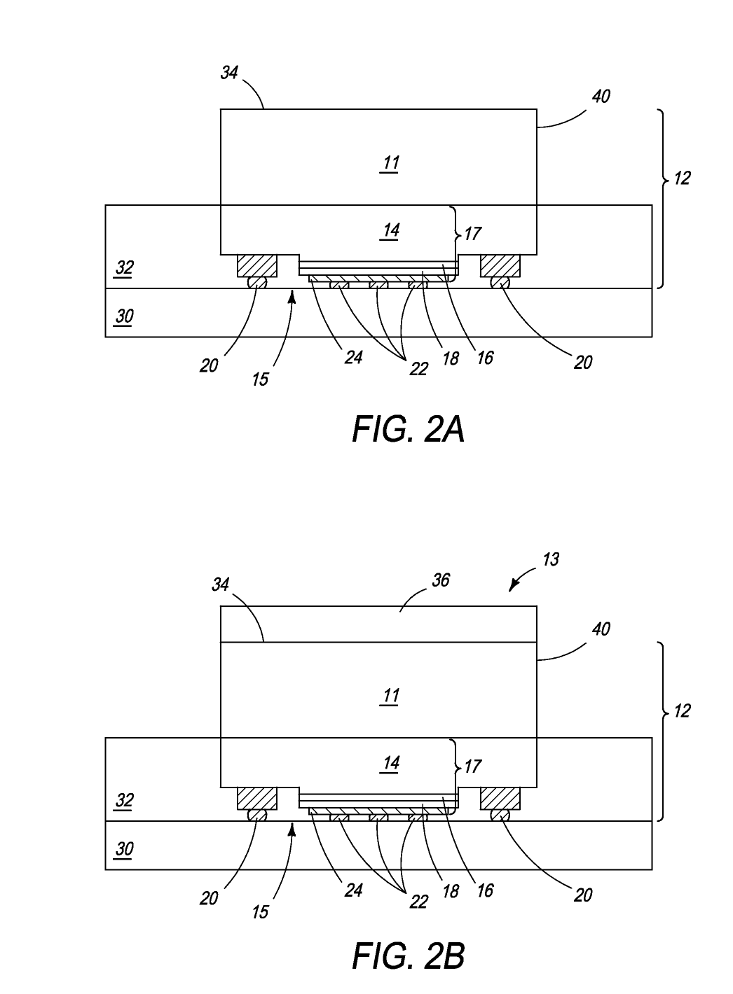

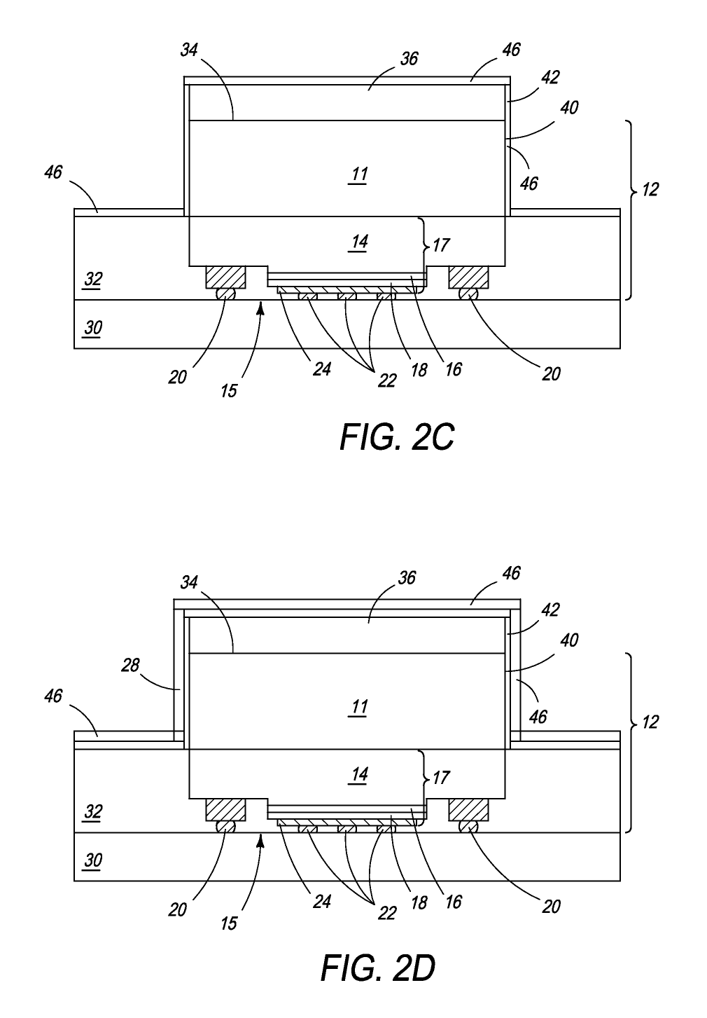

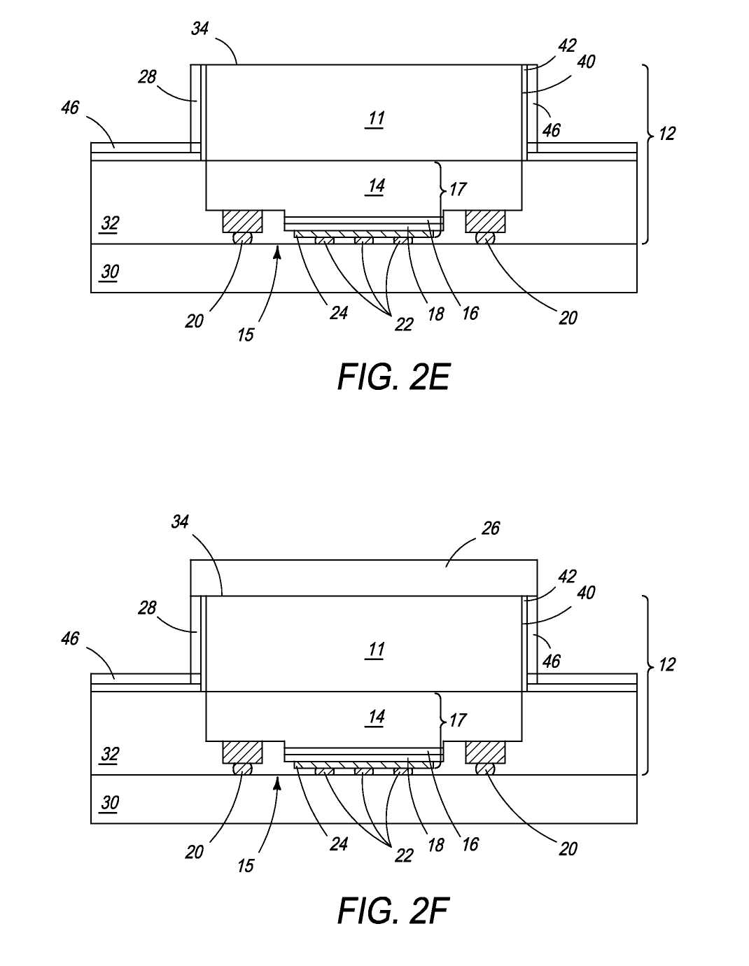

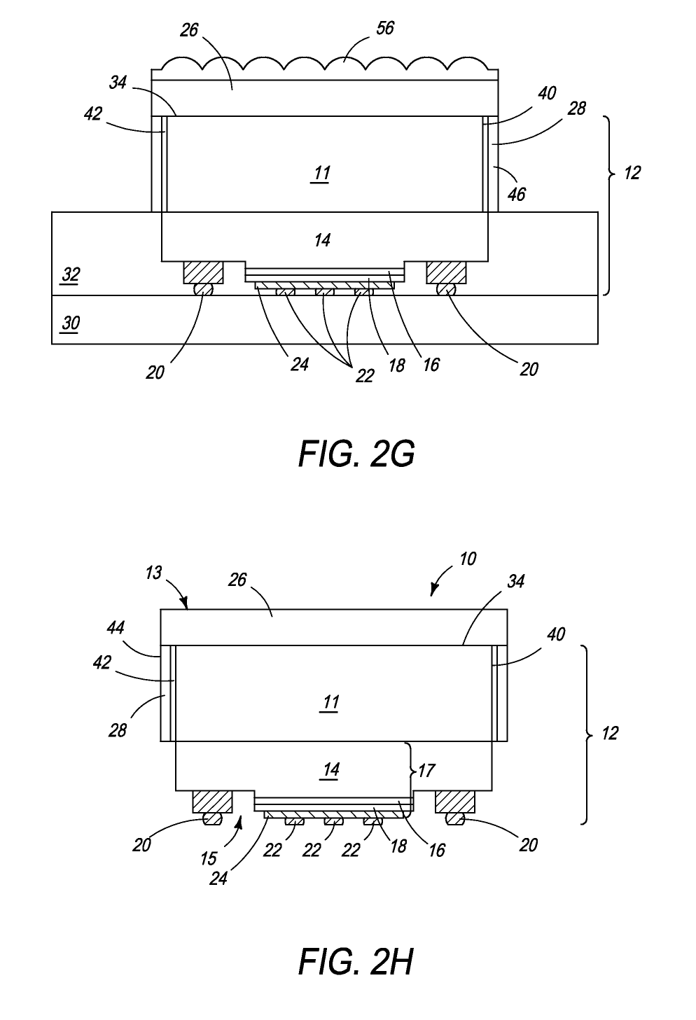

Referring to FIGS. 2A-2H, steps in a method for fabricating the white flip chip light emitting diode (FC LED) 10 are illustrated. In the illustrative embodiment, the fabrication process is shown as being performed at the die level. However, the fabrication process can also be performed at the wafer level followed by a singulation process for separating the individual devices from the wafer.

Initially, as shown in FIG. 2A, the method includes the step of providing the flip chip (LED) die 12 with all of the previously described elements. The flip chip (LED) die 12 can be provided using fabrication processes that are known in the art. For example, suitable fabrication processes are further described in the article entitled “History Of Gallium-Nitride-Based Light-Emitting Diode for Illumination”, by Shuji Nakamura and Michael R. Krames, published in Proceedings of the IEEE, Vol. 101, No. 10, October 2013, which is incorporated herein by reference.

As also shown in FIG. 2A, the method includes the step of forming a backside polymer film 30 on the backside 15 of the flip chip (LED) die 12. The backside polymer film 30 is configured to protect the epitaxial structure 17, the n-pads 20 and the p-pads 22 during the fabrication process for the white flip chip light emitting diode (FC LED) 10. Suitable materials for the backside polymer film 30 include polyethylene, polypropylene, polyester, or polycarbonate. The backside polymer film 30 can be attached to the flip chip (LED) die 12 using an adhesive layer 32. The adhesive layer 32 can comprise an adhesive material such an acrylic polymer formed directly on the backside polymer film 30 or alternately on the backside 15 of flip chip (LED) die 12. The backside polymer film 30 can comprise a tape material with the adhesive layer 32 formed thereon. Alternately, the backside polymer film 30 can comprise a deposited polymer having adhesive qualities, such as polyimide or epoxy in a cured or uncured condition, such that the adhesive layer 32 can be eliminated. In the illustrative embodiment, the adhesive layer 32 covers the vertical sides of the epitaxial structure 17 but not the sides of the sapphire substrate 11.

Next as shown in FIG. 2B, the method includes the step of forming an emitter side polymer film 36 on the planar surface 34 of the sapphire substrate 11, which is the radiation emitter side 13 proximate to the surface of the n-type confinement layer 14. By way of example, the emitter side polymer film 36 can comprise a pressure sensitive adhesive (PSA) tape having a thermal release. One suitable pressure sensitive adhesive (PSA) tape is manufactured by Nitto Denko of Japan under the trademark REVALPHA thermal release tape, and is available in the United States through Semiconductor Equipment Corporation of Moorpark, Calif. 93020. Rather than being a pressure sensitive adhesive (PSA) tape, the emitter side polymer film 36 can comprise a deposited material such as polyimide or epoxy. As shown in FIG. 2A, the emitter side polymer film 36 has a surface area, which preferably is larger than the surface area or footprint of flip chip (LED) die 12.

Next as shown in FIG. 2C, the method includes the step of forming the reflective sidewalls 28 on the vertical sides 40 of the sapphire substrate 11. As shown in FIG. 2C, this step can be performed by depositing a reflective layer 46 directly on the vertical sides 40 of the sapphire substrate 11. As also shown in FIG. 2C, the reflective layer 46 also covers the surface of the emitter side polymer film 36 and the surface of the adhesive 32, which will subsequently be removed. In the deposition process shown in FIG. 2C, the isolation layer 42 is not formed.

Alternately, as shown in FIG. 2D, the step of forming the reflective sidewalls 28 can also include the step of forming the isolation layer 42 on the vertical sides 40 of the sapphire substrate 11, then forming the reflective layer 46 on the isolation layer 42 and then forming the protective layer 44 on the reflective layer 46. The isolation layer 42 and the protective layer 44 can comprise an electrically insulating material, such as SiO₂ or polyimide, formed using a suitable deposition or growth process to a selected thickness. As also shown in FIG. 2C, the reflective layer 46 also forms on the surface of the emitter side polymer film 36 and on the surface of the adhesive layer 32, which will subsequently be removed.

The reflective sidewalls 28 and the reflective layer 46 can comprise a highly reflective metal, such as Ag, Al, Au, Cr, Pt, Pd or alloys of these metals. The reflective sidewalls 28 and the reflective layer 46 can also comprise a stack of metals, such as Ni/Ag/Ni/Au, Ag/Ni/Au, Ti/Ag/Ni/Au, Ag/Pt or Ag/Pd or Ag/Cr. Suitable deposition processes for forming the reflective sidewalls 28 and the reflective layer 46 include electro-deposition, electroless-deposition, chemical vapor deposition (CVD), plasma enhanced chemical vapor deposition (PECVD), physical vapor deposition (PVD), evaporation, and plasma spray. A representative range for the thickness of reflective sidewalls 28 and the reflective layer 46 can be from 0.1 μm to 500 μm.

Next as shown in FIG. 2E, the method includes the step of removing the emitter side polymer film 36 to expose the planar surface 34 of the sapphire substrate 11. With the emitter side polymer film 36 comprising a pressure sensitive adhesive (PSA) tape having a thermal release as previously described, this step can be performed by heating the emitter side polymer film 36 to a selected temperature and then mechanically peeling it away from the sapphire substrate 11. With the emitter side polymer film 36 comprising a deposited polymer, the removing step can be performed by etching using a suitable etchant to dissolve the deposited polymer.

Next as shown in FIG. 2F, the method includes the step of forming a wavelength conversion member 26 on the planar surface 34 of the sapphire substrate 11. Preferably the wavelength conversion member 26 has a surface area that is approximate equal to or slightly larger than the surface area or footprint of the flip chip (LED) die 12. In addition, the wavelength conversion member 26 has a uniform thickness and is planar across its entire surface area, such that the wavelength conversion properties are uniform. In addition, the wavelength conversion member 26 has a thickness selected to provide a low profile for the white flip chip light emitting diode (FC LED) 10.

The forming the wavelength conversion member step can be performed by attaching a pre-fabricated wavelength conversion member to the sapphire substrate 11. U.S. Pat. No. 8,410,508 B2 to Yen et al., which is incorporated herein by reference, discloses a method for fabricating and attaching a pre-fabricated wavelength conversion member. This step can also be performed by depositing the wavelength conversion member 26 directly on the sapphire substrate 11 using a deposition process such as precise dispensing, stamping, jetting or screen printing. U.S. Pat. No. 8,614,453 B2 to Liu et al. discloses a method for fabricating a wavelength conversion member using a deposition process.

Optionally as shown in FIG. 2G, the method can include the step of forming the lens 56 on the wavelength conversion member 26. The lens 56 can comprise a transparent material such as silicone, sapphire, quartz, polymers, co-polymers, polymer based plastics, polycarbonate, glasses, polystyrene, AlO glass, AlON glass, spinel and other optically treated materials having transparency over the wavelength range of the electromagnetic radiation emitted by the flip chip (LED) die 12. In addition, the lens 56 can be formed with a desired shape (e.g., concave, hemispherical), thickness (T) and radius of curvature (R). The lens 56 can comprise one or more layers of material formed using a suitable deposition process such as screen printing, dispensing, precise dispensing, spraying or jetting. Alternately, the lens 56 can comprise a separate member formed using a molding process, which is then bonded to the wavelength conversion member 26.

Next as shown in FIG. 2H, the method includes the step of removing the backside polymer film 30 and the adhesive layer 32. This step can be performed using a suitable method such as etching, mechanical peeling, grinding or polishing. The backside polymer film 30 can also comprise a thermal release material as previously described for the emitter side polymer film 36 such that a thermal release can be performed. For a wafer level process, a singulation step, such as dicing by sawing or etching, can be performed to singulate the white flip chip light emitting diode (FC LED) 10 from the wafer.

As also shown in FIG. 2F, the white flip chip light emitting diode (FC LED) 10 includes the flip chip (LED) die 12; the reflective sidewalls 28 on the vertical sides 40 of the sapphire substrate 11; and the wavelength conversion member 26 on the emitter side 13 of the flip chip (LED) die 12. The white flip chip light emitting diode (FC LED) 10 also includes the n-pads 20 and the p-pads 22 on the backside 15 of the flip chip (LED) die 12 configured for flip chip mounting.

As shown in FIG. 3, the white flip chip light emitting diode (FC LED) 10 can be flip chip mounted to a module substrate 48 to form an (LED) system 50. During a flip chip bonding process, the n-pads 20 can be bonded to n-electrodes 52 on the module substrate 48 to provide an anode, and the p-pads 22 can be bonded to p-electrodes 54 on the module substrate 48 to provide a cathode. Suitable bonding processes include soldering, reflow or conductive adhesive bonding. In addition, low temperature bonding materials such as NiAu solder may be used and formed on the n-pads 20 and the p-pads 22 during the fabrication process.

Thus the disclosure describes an improved method for fabricating a white flip chip light emitting diode (FC LED). While the description has been with reference to certain preferred embodiments, as will be apparent to those skilled in the art, certain changes and modifications can be made without departing from the scope of the following claims.

What is claimed is:

1. A method for fabricating a white flip chip light emitting diode (FC LED) comprising:
providing a flip chip (LED) die comprising a sapphire substrate having a planar surface and a plurality of sides, an n-type confinement layer on the sapphire substrate, a multiple quantum well (MQW) layer on the n-type confinement layer configured to emit electromagnetic radiation, and a p-type confinement layer on the multiple quantum well (MQW) layer;
forming reflective sidewalls on the sides of the sapphire substrate configured to prevent the electromagnetic radiation from transmitting through the sides; and
forming a wavelength conversion member on the planar surface of the sapphire substrate having a uniform thickness and an area equal to or greater than an area of the planar surface configured to change a wavelength of the electromagnetic radiation to produce white light.

2. The method of claim 1 wherein the forming the reflective sidewalls step comprises forming a backside polymer film on a backside of the flip chip (LED) die, forming an emitter side polymer film on the planar surface of the sapphire substrate, and then depositing a reflective metal on the sides of the sapphire substrate.

3. The method of claim 2 wherein the forming the wavelength conversion member comprises removing the emitter side polymer film and attaching a pre-fabricated wavelength conversion member to planar surface of the sapphire substrate.

4. The method of claim 3 wherein the forming the reflective sidewalls step comprises depositing an electrically insulating isolation layer on the sides of the sapphire substrate and then depositing the reflective metal on the isolation layer.

5. The method of claim 4 wherein the forming the reflective sidewalls step further comprises forming a protective layer on an outside surface of the reflective metal.

6. The method of claim 5 further comprising forming a lens on the wavelength conversion member.

7. The method of claim 6 further comprising providing an n-pad on the flip chip (LED) die in electrical contact with the n-type confinement layer and a p-pad on the flip chip (LED) die in electrical contact with the p-type confinement layer and wherein the backside polymer film covers the n-pad and the p-pad during the forming the reflective sidewalls step.

8. A method for fabricating a white flip chip light emitting diode (FC LED) comprising:
providing a flip chip (LED) die having an emitter side, a backside, and a footprint, the flip chip (LED) die comprising a sapphire substrate having a planar surface proximate to the emitter side, a plurality of vertical sides, and an epitaxial structure on the sapphire substrate, the epitaxial structure comprising an n-type confinement layer on the sapphire substrate, a multiple quantum well (MQW) layer on the n-type confinement layer configured to emit electromagnetic radiation, and a p-type confinement layer on the multiple quantum well (MQW) layer;
forming a backside polymer film on the backside of the flip chip (LED) die configured to cover the epitaxial structure while leaving the side of the sapphire substrate exposed;
forming an emitter side polymer film on the planar surface of the sapphire substrate configured to leave the sides exposed;
forming reflective sidewalls on the sides of the sapphire substrate using the backside polymer film to protect the epitaxial structure and the emitter side polymer film to protect the planar surface of the sapphire substrate;
removing the emitter side polymer film to expose the planar surface of the sapphire substrate;
forming a wavelength conversion member on the planar surface of the sapphire substrate having a uniform thickness and a surface area greater than or equal to the footprint of the flip chip (LED) die configured to change a wavelength of the electromagnetic radiation to produce white light; and
removing the backside polymer film.

9. The method of claim 8 wherein the forming the wavelength conversion member step comprises attaching a pre-fabricated wavelength conversion member to the sapphire substrate.

10. The method of claim 8 wherein the forming the reflective sidewalls step forms the reflective sidewalls on the sides of the sapphire substrate but not on the epitaxial structure.

11. The method of claim 8 wherein the emitter side polymer film comprises a pressure sensitive adhesive (PSA) tape having a thermal release and the removing the emitter side polymer film step comprises heating the (PSA) tape.

12. The method of claim 8 wherein the forming the reflective sidewalls step comprises a method selected from the group consisting of electro-deposition, electroless-deposition, chemical vapor deposition (CVD), plasma enhanced chemical vapor deposition (PECVD), physical vapor deposition (PVD), evaporation, and plasma spray.

13. The method of claim 8 wherein the forming the reflective sidewalls step comprises depositing an electrically insulating isolation layer on the sides of the sapphire substrate and then depositing a reflective metal on the isolation layer.

14. The method of claim 8 wherein the forming the reflective sidewalls step further comprises forming a protective layer an outside surface thereof.

15. The method of claim 8 further comprising flip chip mounting the flip chip (LED) die to a module substrate.

16. The method of claim 8 wherein the reflective sidewalls comprise a metal selected from the group consisting of Ag, Al, Au, Cr, Pt, Pd and alloys thereof.

17. The method of claim 8 further comprising forming a lens on the wavelength conversion member.

18. A white flip chip light emitting diode (FC LED) comprising:
a flip chip (LED) die having an emitter side, a backside, and a footprint, the flip chip (LED) die comprising a sapphire substrate having a planar surface proximate to the emitter side, a plurality of vertical sides, and an epitaxial structure on the sapphire substrate, the epitaxial structure comprising an n-type confinement layer on the sapphire substrate, a multiple quantum well (MQW) layer on the n-type confinement layer configured to emit electromagnetic radiation, and a p-type confinement layer on the multiple quantum well (MQW) layer;
a plurality of reflective sidewalls on the sides of the sapphire substrate comprising a metal configured to prevent transmission of the electromagnetic radiation through the sides; and
a wavelength conversion member on the planar surface of the sapphire substrate having a uniform thickness and a surface area greater than or equal to the footprint of the flip chip (LED) die configured to change a wavelength of the electromagnetic radiation to produce white light.

19. The white flip chip light emitting diode (FC LED) of claim 18 further comprising an n-pad on the backside of the flip chip (LED) die in electrical communication with the n-type confinement layer and a p-pad on the backside of the flip chip (LED) die in electrical communication with the p-type confinement layer.

20. The white flip chip light emitting diode (FC LED) of claim 18 further comprising a lens on the wavelength conversion member.

21. The white flip chip light emitting diode (FC LED) of claim 18 wherein the reflective sidewalls comprise a metal selected from the group consisting of Ag, Al, Au, Cr, Pt, Pd and alloys thereof.

22. The white flip chip light emitting diode (FC LED) of claim 18 wherein the reflective sidewalls comprise a metal and an electrically insulating isolation layer between the metal and the sides of the sapphire substrate.

23. The white flip chip light emitting diode (FC LED) of claim 18 wherein the reflective sidewalls comprise a metal, an electrically insulating isolation layer between the metal and the sides of the sapphire substrate, and a protective layer on an outside surface of the metal.

24. The white flip chip light emitting diode (FC LED) of claim 18 wherein the wavelength conversion member comprises a pre-fabricated sheet attached to the sapphire substrate.

25. The white flip chip light emitting diode (FC LED) of claim 18 further comprising a module substrate having a plurality of electrodes bonded to the n-pad and the p-pad configured to form a (LED) system.
